(19) United States
(12) Patent Application Publication
(10) Pub. No.: US 2004/0061530 A1
(43) Pub. Date: Apr. 1, 2004

(54) Clock conversion apparatus, clock conversion method, video display apparatus, and memory address setting method

(76) Inventors: Satoru Tanigawa, Hyogo (JP); Nobutaka Okada, Osaka (JP)

Correspondence Address: WENDEROTH, LIND & PONACK, L.L.P., 2033 K STREET N. W., SUITE 800, WASHINGTON, DC, 20006-1021, US

(21) Appl. No.: 10/637,609

(22) Filed: Aug. 11, 2003

(30) Foreign Application Priority Data
Aug. 12, 2002 (JP) 2002-235019

(51) Int. Cl. H03K 19/00

(52) U.S. Cl. 326/93

(57) ABSTRACT

A clock conversion apparatus includes a memory that can perform writing and reading independently from each other, a first counter circuit for controlling write addresses, a delay adjustment circuit for adjusting a delay time of a reading start reference signal from a writing start reference signal, and a second counter circuit for controlling read addresses from the reading start reference signal, wherein data corresponding to a horizontal sync period are written in the memory over plural times to reduce the capacity of the memory, and a writing start position and a reading start position are delay-adjusted.

### FIELD OF THE INVENTION

The present invention relates to a clock conversion apparatus and a clock conversion method for converting a digital signal processed by a first clock into a digital signal synchronized with a second clock, using a memory. Further, the invention relates to a video display apparatus having the clock conversion apparatus, and a memory address setting method thereof.

### BACKGROUND OF THE INVENTION

In recent years, video signal processing using digital signal processing techniques has been frequently used to realize high-quality and high-functionality video signals in television receivers. Further, when performing digital video signal processing, an input video signal is compressed or expanded in the horizontal direction to pass the digital data between different kinds of clocks, or change the picture size, and a clock conversion apparatus capable of passing digital data between different kinds of clocks has increasingly become important.

As for expansion/compression of an input video signal, for example, Japanese Published Patent Application No. Hei. 8-223479 discloses “a sampling frequency conversion circuit” in which expansion or compression of an input video signal in the horizontal direction is carried out using a one-line memory capable of perform writing and reading with clocks having different frequencies, and an interpolation circuit for compressing or expanding a digital video signal in the horizontal direction.

That is, in the conventional clock conversion apparatus, when an interpolation factor which is obtained by combining the frequency conversion ratio and the scaling factor of expansion or compression is less than “1”, compressive interpolation is initially carried out using the interpolation factor, and then the digital video signal is written in and read from a line memory. Conversely, when the interpolation factor is equal to or larger than “1”, the video data is read from the line memory, and extensive interpolation is carried out using the interpolation factor. The writing end performs the above-mentioned operation by the clock before conversion while the reading end performs the operation by the clock after conversion, thereby performing horizontal expansion/compression and conversion of sampling frequency at the same time, whereby degradation in horizontal resolution can be minimized in digital video signal processing in which conversion of sampling frequency and expansion or compression of an image in the horizontal direction should be carried out.

However, the conventional clock conversion apparatus needs a one-line memory that can hold one horizontal line of data when compressing/expanding a digital signal in the horizontal direction, resulting in an increase in circuit scale.

Further, in the broadcasting systems such as NTSC, PAL, and SECAM, the memory size for one-line period varies depending on differences in processing clock frequency or horizontal frequency, and therefore, the memory size must be adapted to the maximum size to cope with all of the broadcasting systems, resulting in an increase in circuit scale.

### SUMMARY OF THE INVENTION

The present invention is made to solve the above-described problems and has for its object to provide a clock conversion apparatus and a clock conversion method, which can significantly reduce the size of required memory when performing compression/expansion in the horizontal direction, or passing a digital signal between different clocks.

Further, it is another object of the present invention to provide a video display apparatus and a memory address setting method thereof, which can significantly reduce the size of a required memory when passing a digital signal between different clocks, by using the above-described clock conversion apparatus.

Other objects and advantages of the invention will become apparent from the detailed description that follows. The detailed description and specific embodiments described are provided only for illustration since various additions and modifications within the scope of the invention will be apparent to those of skill in the art from the detailed description.

According to a first aspect of the present invention, there is provided a clock conversion apparatus for converting data synchronized with a first clock into data synchronized with a second clock, and the apparatus comprises: a memory having addresses less than addresses required for storage of data corresponding to a predetermined period, and being able to execute a writing operation and a reading operation independently from each other using a clock for writing and a clock for reading, respectively; a first counter circuit for counting the first clock, and generating write addresses of the memory so that the data corresponding to the predetermined period can be written into the memory over plural times; and a second counter circuit for counting the second clock, and generating read addresses of the memory so that the data corresponding to the predetermined period, which have been written in the memory, can be read from the memory over plural times. Therefore, the data synchronized with the first clock can be converted to the data synchronized with the second clock, employing a reduced memory capacity, without the data reading overtaking the data writing into the memory or being overtaken by the data writing into the memory.

According to a second aspect of the present invention, there is provided a clock conversion apparatus for converting data synchronized with a first clock into data synchronized with a second clock, and the apparatus comprises: a memory having addresses less than addresses required for storage of data corresponding to a predetermined period, and being able to execute a writing operation and a reading operation independently from each other using a clock for writing and a clock for reading, respectively; a first counter circuit for starting count of the first clock on receipt of a writing start reference signal indicating a writing start reference timing of the memory, and generating write addresses of the memory so that the data corresponding to the predetermined period can be written in the memory over plural times; and a second counter circuit for starting count of the second clock from a reading start reference signal indicating a reading start reference timing of the memory, and generating read addresses of the memory so that the data corresponding to the predetermined period, which have been written in the memory, can be read over plural times. Therefore, the data synchronized with the first clock can be converted to the data synchronized with the second clock, employing a reduced memory capacity, without the data reading overtaking the data writing into the memory or being overtaken by the data writing into the memory.

According to a third aspect of the present invention, there is provided a clock conversion apparatus for converting data synchronized with a first clock into data synchronized with a second clock, and the apparatus comprises: a memory having addresses less than addresses required for storage of data corresponding to a predetermined period, and being able to execute a writing operation and a reading operation independently from each other using a clock for writing and a clock for reading, respectively; a first counter circuit for starting count of the first clock on receipt of a writing start reference signal indicating a writing start reference timing of the memory, and generating write addresses of the memory so that the data corresponding to the predetermined period can be written into the memory over plural times; a second counter circuit for starting count of the second clock from a reading start reference signal indicating a reading start reference timing of the memory, and generating read addresses of the memory so that the data corresponding to the predetermined period, which have written in the memory, can be read over plural times; and a delay adjustment circuit capable of adjusting a delay time, which delays the writing start reference signal to generate the reading start reference signal. Therefore, the data synchronized with the first clock can be converted to the data synchronized with the second clock, employing a reduced memory capacity, without the data reading overtaking the data writing into the memory or being overtaken by the data writing into the memory.

According to a fourth aspect of the present invention, there is provided a clock conversion apparatus for converting data synchronized with a first clock into data synchronized with a second clock, and the apparatus comprises: a memory having addresses less than addresses required for storage of data corresponding to a predetermined period, and being able to execute a writing operation and a reading operation independently from each other using a clock for writing and a clock for reading, respectively; a first counter circuit for starting count of the first clock on receipt of a writing start reference signal indicating a writing start reference timing of the memory, and generating write addresses of the memory, which repeat increase or decrease within a predetermined range of addresses of the memory, so that the data corresponding to the predetermined period can be written in the memory over plural times; a second counter circuit for starting count of the second clock from a reading start reference signal indicating a reading start reference timing of the memory, and generating read addresses of the memory, which repeat increase or decrease within a predetermined range of addresses of the memory, so that the data corresponding to the predetermined period which are written in the memory can be read over plural times; and a delay adjustment circuit capable of adjusting a delay time, which delays the writing start reference signal to generate the reading start reference signal. Therefore, the data synchronized with the first clock can be converted to the data synchronized with the second clock, employing a reduced memory capacity, without the data reading overtaking the data writing into the memory or being overtaken by the data writing into the memory.

According to a fifth aspect of the present invention, there is provided a clock conversion apparatus for converting data synchronized with a first clock into data synchronized with a second clock, and the apparatus comprises: a memory having addresses less than addresses required for storage of data corresponding to a predetermined period, and being able to execute a writing operation and a reading operation independently from each other using a clock for writing and a clock for reading, respectively; a first counter circuit for starting count of the first clock on receipt of a writing start reference signal indicating a writing start reference timing of the memory, and generating write addresses of the memory so that the write addresses repeat increase or decrease within a predetermined range of addresses of the memory, and the last increase or decrease for every predetermined period is carried out within a range of addresses narrower than the predetermined range of addresses, thereby enabling writing of the data corresponding to the predetermined period into the memory over plural times; a second counter circuit for starting count of the second clock from a reading start reference signal indicating a reading start reference timing of the memory, and generating read addresses of the memory so that the read addresses repeat increase or decrease within a predetermined range of addresses of the memory, and the last increase or decrease for every predetermined period is carried out within a range of addresses narrower than the predetermined range of addresses, thereby enabling reading of the data corresponding to the predetermined period, which have been written in the memory, over plural times; and a delay adjustment circuit capable of adjusting a delay time, which delays the writing start reference signal to generate the reading start reference signal. Therefore, the data synchronized with the first clock can be converted to the data synchronized with the second clock, employing a reduced memory capacity, without the data reading overtaking the data writing into the memory or being overtaken by the data writing into the memory.

According to a sixth aspect of the present invention, in the clock conversion apparatus according to any of the first to fifth aspects, the data corresponding to the predetermined period are written in the memory using such write addresses that a multiple of a maximum write address value becomes close to the number of samples of data that are sampled at the first clock within the predetermined period; and the data are read from the memory using such read addresses that a multiple of a maximum read address value becomes close to the number of samples of data that are sampled at the second clock. Therefore, the writing start position and the reading start position are adjusted to half the maximum number of addresses, whereby the data synchronized with the first clock can be converted to the data synchronized with the second clock, without the data reading overtaking the data writing into the memory or being overtaken by the data writing into the memory.

According to a seventh aspect of the present invention, in the clock conversion apparatus according to any of the first to fifth aspects, the data corresponding to the predetermined period are written in the memory using such write addresses that a multiple of a maximum write address value becomes close to the number of samples of data that are sampled at the first clock within the predetermined period; and the data are read from the memory using read addresses having a maximum value equal to the maximum value of the write addresses. Therefore, the writing start position and the reading start position are adjusted to half the maximum number of addresses, whereby the data synchronized with the first clock can be converted to the data synchronized with the second clock, without the data reading overtaking the data writing into the memory or being overtaken by the data writing into the memory.

According to an eighth aspect of the present invention, in the clock conversion apparatus according to any of the first to fifth aspects, the predetermined period is one horizontal sync period. Therefore, the capacity of a memory that needs a capacity corresponding to one horizontal sync period can be reduced.

According to a ninth aspect of the present invention, in the clock conversion apparatus according to any of the first to fifth aspects, the first counter circuit comprises a write address counter for counting the first clock to create the write addresses; and a write maximum value limiter for comparing the write address outputted from the write address counter with a settable write maximum value, and resetting the write address counter when the write address becomes equal to the write maximum value. Therefore, the first counter circuit is implemented by a resettable counter and a comparison circuit for resetting the counter when the count value reaches the upper limit, whereby the first counter circuit can be realized in a small-scale circuit construction.

According to a tenth aspect of the present invention, in the clock conversion apparatus according to any of the first to fifth aspects, the second counter circuit comprises a read address counter for counting the second clock to create the read addresses; and a read maximum value limiter for comparing the read address outputted from the read address counter with a settable read maximum value, and resetting the read address counter when the read address becomes equal to the read maximum value. Therefore, the second counter circuit can be realized in the same construction as the first counter circuit.

According to an eleventh aspect of the present invention, there is provided a clock conversion method for converting data synchronized with a first clock into data synchronized with a second clock, and the method comprises: generating write addresses on the basis of the first clock so that data corresponding to a predetermined period are written over plural times into a memory which has addresses less than addresses required for storage of the data corresponding to the predetermined period, and is able to execute a writing operation and a reading operation independently from each other using a clock for writing and a clock for reading, respectively; and generating read addresses on the basis of the second clock so that the data corresponding to the predetermined period are read from the memory over plural times. Therefore, the data synchronized with the first clock can be converted to the data synchronized with the second clock, employing a reduced memory capacity, without the data reading overtaking the data writing into the memory or being overtaken by the data writing into the memory.

According to a twelfth aspect of the present invention, there is provided a video display apparatus comprising a first video processing unit for subjecting a digital video signal to first video processing on the basis of a first clock; a clock conversion unit for converting the digital video signal which is outputted from the first video processing unit and synchronized with the first clock into a digital video signal synchronized with a second clock; a second video processing unit for subjecting the digital video signal outputted from the clock conversion unit to second video processing on the basis of the second clock; and a display device for displaying the digital video signal outputted from the second video processing unit; and the clock conversion unit comprises: a memory having a capacity less than one horizontal line of the digital video signal outputted from the first video processing unit, and being able to execute a writing operation and a reading operation independently from each other using a clock for writing and a clock for reading, respectively; and a memory controller for controlling the memory so that the digital video signal outputted from the first video processing unit are written into the memory over plural times for every horizontal line, and the data corresponding to each horizontal line, which are written in the memory, can be read over plural times. Therefore, when performing transition of data from on the first clock to on the second clock for the second video processing after the first video processing has ended, the memory capacity can be reduced, and the transition of data from on the first clock to on the second clock can be carried out without the data reading overtaking the data writing into the memory or being overtaken by the data writing into the memory.

According to a thirteenth aspect of the present invention, in the video display apparatus according to the twelfth aspect, the memory controller comprises a first counter circuit for starting count of the first clock on receipt of a writing start reference signal indicating a writing start reference timing of the memory, and generating write addresses of the memory so that the one horizontal line of data can be written into the memory over plural times; and a second counter circuit for starting count of the second clock from a reading start reference signal indicating a reading start reference timing of the memory, and generating read addresses of the memory so that the one horizontal line of data which are written in the memory can be read over plural times. Therefore, when performing transition of data from on the first clock to on the second clock for the second video processing after the first video processing has ended, the memory capacity can be reduced by performing address control using the counter circuit, and the transition of data from on the first clock to on the second clock can be carried out without the data reading overtaking the data writing into the memory or being overtaken by the data writing into the memory.

According to a fourteenth aspect of the present invention, there is provided a memory address setting method for a video display apparatus comprising: a first video processing unit for subjecting a digital video signal to first video processing on the basis of a first clock; a clock conversion unit for converting the digital video signal which is outputted from the first video processing unit and synchronized with the first clock into a digital video signal synchronized with a second clock; a second video processing unit for subjecting the digital video signal outputted from the clock conversion unit to second video processing on the basis of the second clock; and a display device for displaying the digital video signal outputted from the second video processing unit; and the clock conversion unit comprises a memory having addresses less than addresses required for storage of data corresponding to a predetermined period, and being able to execute a writing operation and a reading operation independently from each other using a clock for writing and a clock for reading, respectively; a first counter circuit for generating write addresses of the memory on the basis of the first clock so that the data corresponding to the predetermined period are written over plural times; and a second counter circuit for generating read addresses of the memory on the basis of the second clock so that the data corresponding to the predetermined period are from the memory over plural times; and the memory address setting method comprises a step of determining a broadcasting system of the digital video signal inputted to the first video processing unit; a step of detecting upper limits or lower limits of count values of the first and second counter circuits corresponding to the determined broadcasting system, according to the broadcasting system; and a step of setting the detected upper limits or lower limits of the count values on the first and second counter circuits. Therefore, when performing transition of data from on the first clock to on the second clock for the second video processing after the first video processing has ended, the memory capacity can be reduced without changing the circuit construction, and the transition of data from on the first clock to on the second clock can be carried out without the data reading overtaking the data writing into the memory or being overtaken by the data writing into the memory.

### BRIEF DESCRIPTION OF THE DRAWINGS

FIG. 1 is a block diagram illustrating the construction of a clock conversion apparatus according to a first embodiment of the present invention.

FIGS. 2(a) and 2(b) are block diagrams illustrating the internal structures of first and second counter circuits included in the clock conversion apparatus according to the first embodiment, more specifically, FIG. 2(a) is a block diagram illustrating the internal structures of a write address counter, a read address counter, a write maximum value limiter, and a read maximum value limiter, and FIG. 2(b) is a block diagram illustrating the internal structures of decoders included in the write maximum value limiter and the read maximum value limiter.

FIG. 3 is a block diagram illustrating the internal structure of a delay adjustment circuit included in the clock conversion apparatus according to the first embodiment.

FIG. 4 is a diagram illustrating write addresses and read addresses when the clock conversion apparatus according to the first embodiment uses an NTSC-system 256 address memory.

FIG. 5 is a diagram illustrating write addresses and read addresses when the clock conversion apparatus according to the first embodiment uses an NTSC-system 256 address memory.

FIG. 6 is a diagram illustrating write addresses and read addresses when the clock conversion apparatus according to the first embodiment uses a PAL-system 256 address memory.

FIG. 7 is a diagram illustrating write addresses and read addresses when the clock conversion apparatus according to the first embodiment uses a PAL-system 256 address memory.

FIG. 8 is a diagram illustrating write addresses and read addresses when the clock conversion apparatus according to the first embodiment uses an NTSC-system 128 address memory.

FIG. 9 is a diagram illustrating write addresses and read addresses in the case where a first clock and a second clock have different frequencies when the clock conversion apparatus according to the first embodiment uses an NTSC-system 256 address memory.

FIG. 10 is a block diagram illustrating the construction of a television receiver having a video display apparatus according to a second embodiment of the present invention.

FIG. 11 is a flowchart illustrating an operation for controlling the video display apparatus according to the second embodiment using a microcomputer.

### DETAILED DESCRIPTION OF THE PREFERRED EMBODIMENTS

[Embodiment 1]

Hereinafter, a first embodiment of the present invention will be described with reference to the drawings.

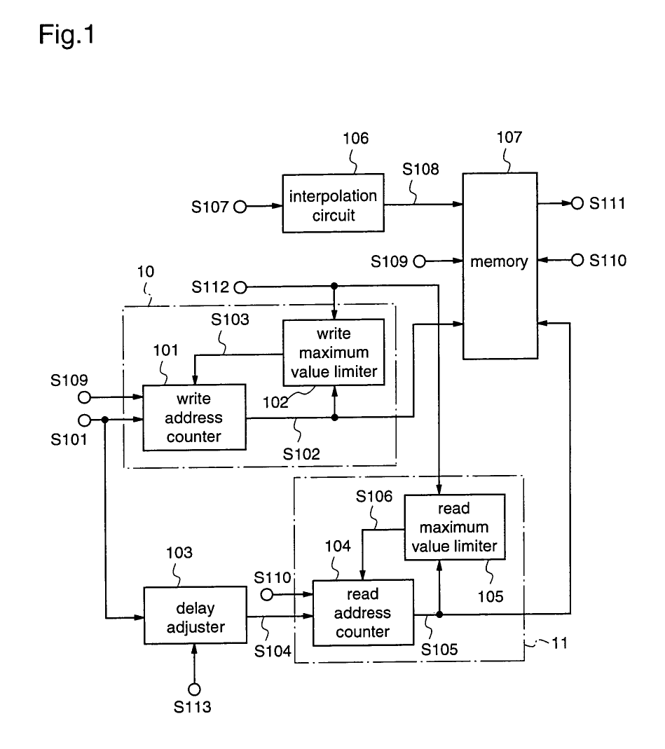

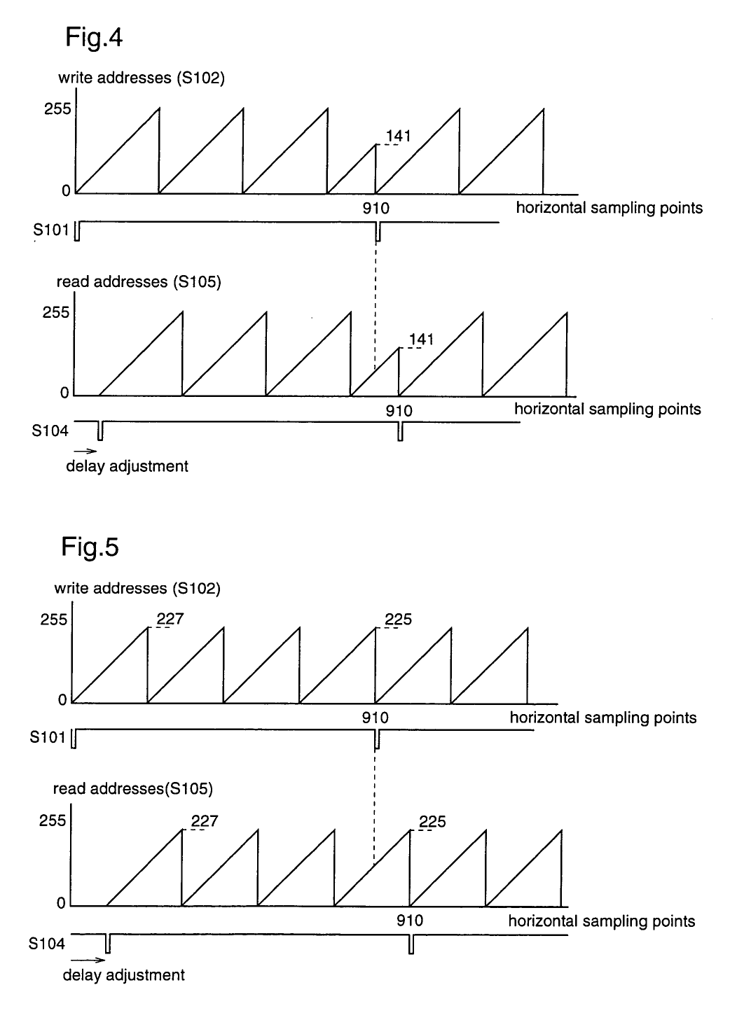

FIG. 1 is a block diagram illustrating the construction of a clock conversion apparatus according to the first embodiment. In FIG. 1, reference numeral 101 denotes a write address counter for controlling write addresses. The write address counter 101 starts up-counting of a first clock (clock for writing) S109 by a horizontal sync pulse signal (writing start reference signal) S101, and outputs write addresses S102 of a memory 107 as count values. The write address counter 101 is once reset by the next horizontal sync pulse signal S101, and starts next up-counting. Reference numeral 102 denotes a write maximum value limiter (maximum value limiter circuit) for write addresses. The write maximum value limiter 102 resets the write address counter 101 by a write address reset signal S103 when the write address S102 becomes equal to a value that is set by a maximum value control signal S112. Reference numeral 10 denotes a first counter circuit comprising the write address counter 101 and the write maximum value limiter 102. The first counter circuit 10 counts the first clock S109, and creates write addresses S102 of the memory 107 so that data corresponding to one horizontal period (predetermined period), i.e., one horizontal sync line of data, can be written in the memory 107 over plural times. The first counter circuit 10 creates the write addresses S102 so that up-counting is repeated within a predetermined range of addresses of the memory 107 as shown in FIG. 7, or the last up-counting in one horizontal period is carried out within a range narrower than the predetermined range of addresses as shown in FIGS. 4˜6 and 8.

Reference numeral 103 denotes a delay adjustment circuit for generating a read reference pulse (read start reference signal) S104 by delaying the horizontal sync pulse S101 according to the value of a delay difference signal S113. Reference numeral 104 denotes a read address counter (counter circuit) for controlling read addresses. The read address counter 104 starts up-counting of a second clock (clock for reading) S110 according to the read reference pulse S104 from the delay adjustment circuit 103, and outputs read addresses S105 of the memory 107 as count values. The read address counter 104 is once reset by the next read reference pulse S104, and starts next up-counting. Reference numeral 105 denotes a read maximum value limiter (maximum value limiter circuit) for read addresses. The read maximum value limiter 105 resets the read address counter 104 by a read address reset signal S106 when the read address S105 becomes equal to a value that is set by the maximum value control signal S112. Reference numeral 11 denotes a second counter circuit comprising the read address counter 104 and the read maximum value limiter 105. The second counter circuit 11 counts the second clock S110, and creates read addresses S105 of the memory 107 so that one horizontal period (predetermined period) of data can be read from the memory 107 over plural times. The second counter circuit 11 creates the read addresses SLOS so that up-counting is repeated within a predetermined range of addresses of the memory 107 as shown in FIG. 7, or the last up-counting in one horizontal period is carried out within a range narrower than the predetermined range of addresses as shown in FIGS. 4˜6 and 8.

Reference numeral 106 denotes an interpolation circuit for creating interpolation data of an inputted video signal S107, and reference numeral 107 denotes a memory which can control writing and reading separately. The memory 107 has addresses less than addresses required for holding a video signal corresponding to one horizontal sync period (data corresponding to a predetermined period), receives an interpolated video signal S108, and outputs an output signal S111.

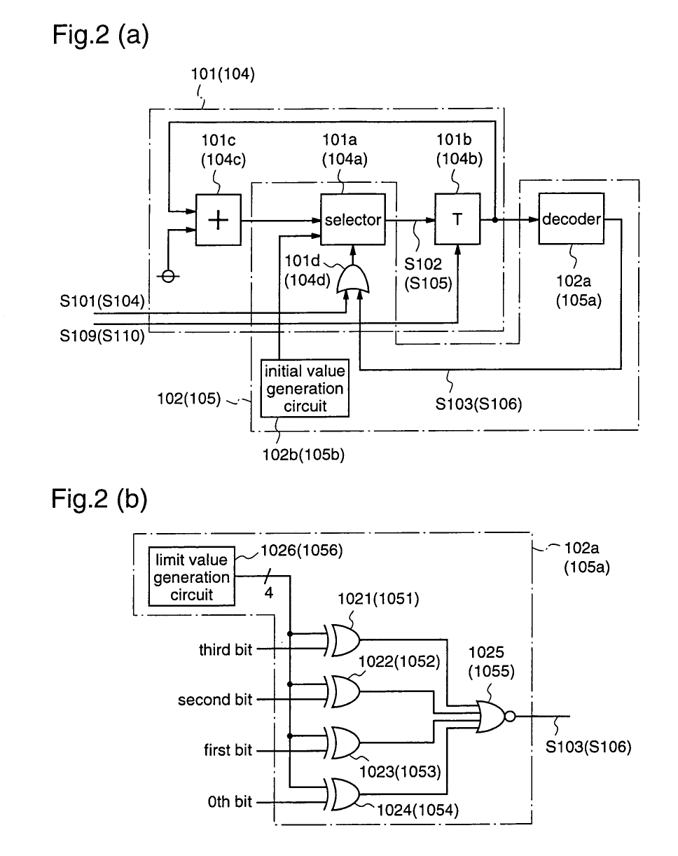

FIG. 2(a) is a block diagram illustrating the construction of the first counter 10 (the second counter 11) shown in FIG. 1. In FIG. 2(a), reference numeral 101a (104a) denotes a selector, numeral 101b (104b) denotes a flip-flop for delaying the output of the selector 101a (104a) by one clock period of the first clock S109 (second clock S110), and numeral 101c (104c) denotes an adder for adding “1” to the output of the flip-flop 101b (104b). The write address counter 101 (the read address counter 104) is constituted by the selector 101a (104a), the flip-flop 101b (104b), and the adder 101c (104c).

Reference numeral 102a (105a) denotes a decoder for decoding the output of the T flip-flop 101b (104b), numeral 102b (105b) denotes an initial value generation circuit for generating a initial count value to be set on the counter 101a (104a), numeral 101d denotes an OR circuit for outputting an OR between the output of the decoder 102a and the horizontal sync pulse S101 to a control input of the selector 101a, and numeral 104d denotes an OR circuit for outputting an OR between the output of the decoder 105a and the read reference pulse S104 to a control input of the selector 104a. The write maximum value limiter 102 (the read maximum value limiter 105) is constituted by the selector 101a (104a), the decoder 102a (105a), the initial value generation circuit 102b (105b), and the OR circuit 101d (104d).

FIG. 2(b) illustrates the decoder 102a (105a) shown in FIG. 2(a), which is constituted by comparators. In FIG. 2(b), reference numerals 1021, 1022, 1023, and 1024 denote exclusive OR circuits each receiving bit outputs of the same weight from the limit value generation circuit 1026 and the flip-flop 101b, numeral 1025 denotes a NOR circuit which receives the outputs of the exclusive OR circuits 1021, 1022, 1023, and 1024, numerals 1051, 1052, 1053, and 1054 denote exclusive OR circuits each receiving bit outputs of the same weight from the limit value generation circuit 1056 and the flip-flop 104b, and numeral 1055 denotes a NOR circuit which receives the outputs of the exclusive OR circuits 1051, 1052, 1053, and 1054.

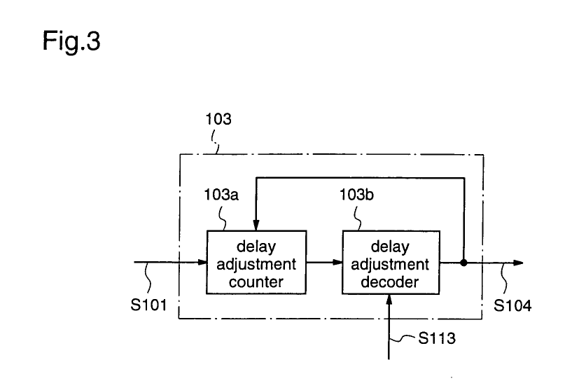

FIG. 3 is a block diagram illustrating the construction of a delay adjustment circuit shown in FIG. 1. In FIG. 3, reference numeral 103a denotes a delay adjustment counter for counting the horizontal sync pulse S101, and numeral 103b denotes a delay adjustment decoder for decoding the count value of the delay adjustment counter 103a.

Hereinafter, the operation of the clock conversion apparatus constructed as described above will be described.

In FIG. 1, reference numeral S101 denotes a horizontal sync pulse signal which is a reference pulse for determining a write address starting position (writing start reference signal). When the horizontal sync pulse signal S101 is input, the write address counter 101 is reset to an initial address value “0”, and the write address S102, i.e., the output of the write address counter 101, is updated to the value “0”, and thereafter, the write address S102 is up-counted every time the first clock S109 is input. When the frequency of the first clock S109 is set higher than the frequency of the second clock S110, data are written in the memory 107 while thinning out sampling points, and therefore, the write address counter 101 halts the up-counting during the sampling period when the thinning-out is carried out so as not to write data in the memory 107.

As described above, the write address counter 101 counts the horizontal sync pulse signal S101, and outputs the write address S102. The write maximum value limiter 102 compares the write address S102 with the write address maximum value that is defined by the maximum value control signal S112, and outputs a write address reset signal S103 when the write address S102 and the write address maximum value become equal to each other. The write address reset signal S103 resets the write address counter 101 to the initial address value “0”.

Further, reference numeral S109 denotes a first clock as a clock at the writing side of the memory 107, and the input video signal S107 processed by the first clock S109 is reduced in the number of sampling points or expanded by the interpolation circuit 106. The video signal S108 interpolated by the interpolation circuit 106 is written in a specified address of the memory 107 according to the first clock S109 and the write address S102.

On the other hand, the horizontal sync pulse S101 is input to the delay adjustment circuit 103, and the delay adjustment circuit 103 outputs a read reference pulse S104 having an amount of delay based on a delay difference signal S113 that is determined by a delay difference setting register (not shown), with reference to the horizontal sync pulse S101, thereby determining a read address starting position. On receipt of the read reference pulse S104, the read address counter 104 is reset to the initial address value “0”, and the read address S105 outputted from the address counter 104 is updated to this value “0”, and thereafter, the read address S105 is up-counted every time the second clock S110 is input. The read maximum value limiter 105 compares the read address S105 with the read address maximum value that is defined by the maximum value control signal S112, and outputs a read address reset signal S106 when the read address and the read address maximum value become equal to each other. The read address reset signal S106 resets the read address counter 104 to the initial address value “0”.

Furthermore, reference numeral S110 denotes a second clock as a clock at the reading side of the memory 107, and the signal written in the memory 107 is read as an output signal S111 according to the read address S105 every time the second clock S110 is generated, whereby the input signal processed by the first clock S109 is converted into a signal processed by the second clock S110, thereby obtaining an output signal.

Hereinafter, the operations of the first counter 10 and the second counter 11 will be described.

In FIG. 2(a), when the value of the horizontal sync pulse S101 (read reference pulse S104) initially becomes “L”, the selector 101a (104a) selects the initial value outputted from the initial value generation circuit 102b (105b), and the output of the selector 101a (104a) is one clock delayed by the flip-flop 111b (104b) and then fed back to the adder 101c (104c). The fedback value is added to the power supply voltage level “1” by the adder 101c (104c), and the result of addition is output to the selector 101a (104a). At this time, since the value of the horizontal sync pulse S101 (read reference pulse S104) has just changed to “H”, the result of addition is selected by the selector 101a (104a) to be output to the flip-flop 101b (104b). By repeating this cycle for every clock, the counter 101a (104a) increments the count value by “1” for every clock.

The count value is also supplied to the decoder 102a (105a), and the decoder 102a (105a) decodes the count value. When the result of decoding matches a value that has previously been set in the decoder, the decoder 102a (105a) outputs a write address reset signal S103 (read address reset signal S106) to make the selector 101a (104a) select the output of the initial value generation circuit 102b (105b) via the OR circuit 101d (104d). Thereby, the count value of the counter 101 (104) is once reset, and the above-described operation is repeated until the value of the horizontal sync pulse S101 (read reference pulse S104) becomes “L”. As a result, the counter 101a (104a) repeats sawtooth-shaped up-counting as shown in FIG. 4.

When the decoder 102a (105a) has the 4-bit construction as shown in FIG. 2(b), the output of the flip-flop 101b (104b) and the output of the reset value generation circuit 1026 (1056) are compared for every bit by the exclusive OR circuits 1021˜1024 (1051˜1054). When the comparison results obtained by the exclusive OR circuits become equal to each other, the NOR circuit 1025 (1055) outputs a reset signal S103 (S106) of “H”.

FIG. 4 shows the relationship between the horizontal sampling points and the write addresses (read addresses) of the memory in the case where a standard signal is input in the NTSC system, a sampling frequency four times as high as a chrominance subcarrier frequency (3.58 MHz) is used for both the first clock S109 and the second clock S110, and there is no thinning-out in the horizontal direction. In this case, a memory having no thinning-out in the horizontal direction and being constituted by 256 addresses is employed as an example. In FIG. 4, the abscissa shows the horizontal sampling points, and the address value increments by “1” every time the number of horizontal sampling points increments by 1, and the address value returns to the initial address value “0” when the address exceeds the maximum value. In this case, data are stored in the memory 107 using such write addresses that a multiple of the maximum write address “255” becomes close to “910” that is the number of samples of data sampled by the first clock in the horizontal period, and a value equal to the maximum write address is used as the maximum read address.

FIG. 5 shows the relationship between the horizontal sampling points and the write addresses (read addresses) of the memory in the case where a standard signal is input in the NTSC system, a sampling frequency four times as high as a chrominance subcarrier frequency (3.58 MHz) is used for both the first clock S109 and the second clock S110, and there is no thinning-out in the horizontal direction. More specifically, FIG. 5 shows the relationship between the horizontal sampling points and the write addresses (read addresses) of the memory in the case where limiter processing is added in controlling writing and reading of data into/from the memory, wherein the memory is constituted by 256 addresses. In FIG. 5, the abscissa shows the horizontal sampling points, and the address value increments by “1” every time the number of horizontal sampling points increments by 1, and the address value returns to the initial address value “0” when the address exceeds the maximum value.

In this case, data are stored in the memory 107 using such write addresses that a multiple of the maximum write address “227” becomes close to “910” that is the number of samples of data sampled by the first clock in the horizontal period, and a value equal to the maximum write address is used as the maximum read address.

In FIG. 4, when the horizontal sync pulse S101 is input, the write address S102 is reset to the initial address value “0”, and the write address S102 is up-counted at every first clock. Since the memory size for one line period is 910 addresses in the NTSC broadcasting, when the maximum value of the maximum value control signal S112 is set at “255”, the address value returns to “0” when it exceeds the maximum value “255”. Once the write maximum value limiter 102 is set as mentioned above, the write address counter 101 repeats the above-mentioned operation plural times for every one line period. More specifically, in the example shown in FIG. 4, up-counting from the initial address value “0” to the maximum address value “255” is repeated three times during a period from initial reset to when the next horizontal sync pulse S101 is inputted, and the fourth up-counting is interrupted at “141” that is the line final value of the write address S112. The reason is as follows. During the fourth up-counting, the count of the horizontal sampling points reaches “910”, and the write address counter 102 is reset by the next horizontal sync pulse S101 at the instance when “910” is counted. The timing when the counter 102 is reset corresponds to “141” in the fourth up-counting (910=256×3+142)

On the other hand, the read address S105 is also up-counted as in the case of the write address S102. However, as for the start position of the read address S105, “71” that is half the line final value of the write address is set on the delay adjustment circuit 103 as a delay difference, according to the delay control signal S113. Thereby, the read address S105 is up-counted with a delay corresponding to 72 horizontal sampling points from the write address S102. Therefore, even when the horizontal sync pulse is disordered and thereby a deviation of 71 clocks occurs in the horizontal direction when a video tape in which a non-standard signal of the NTSC system is recorded is played with a video tape recorder, it is possible to constitute a standard signal without the data reading overtaking the data writing or being overtaken by the data writing when reading the data from the memory.

At this time, the read reference pulse S104 can be output at a timing delayed by a predetermined period from the horizontal sync pulse S101 by constituting the delay adjustment circuit 103 as shown in FIG. 3. That is, when a single horizontal sync pulse S101 is input, the delay adjustment counter 103a starts self-up-counting with the pulse S101 as a trigger. When the count value becomes equal to the value of the delay control signal S113 that is set on the delay adjustment decoder 103b, the delay adjustment decoder 103b outputs the read reference pulse S104, and thereby the delay adjustment counter 103a is reset. It is possible to output the read reference pulse S104 at a timing delayed by a desired period from the horizontal sync pulse S101, by changing the value that is set on the delay adjustment decoder 103b.

On the other hand, with reference to FIG. 5, when the horizontal sync pulse S101 is input, the write address S102 is reset to the initial address value “0”, and the write address S102 is up-counted at every first clock. Since the maximum value of the write address S112 is set at “227”, the address value returns to “0” when it exceeds the maximum value “227”. This operation is repeated three times until the next horizontal sync pulse S101 is input, and the line final value of the write address S112 from when the next horizontal sync pulse S101 is input to when the write address counter 102 is reset becomes “225” (910=228×3+226). As for the start position of the read address S105, for example, “112” that is half the line final value of the write address is set as a delay difference according to the delay control signal S113. Therefore, even when the horizontal sync pulse is disordered and thereby a deviation of 112 clocks occurs in the horizontal direction when a video tape on which a non-standard signal of the NTSC system is recorded is played back with a video tape recorder, it is possible to constitute a standard signal without the data reading overtaking the data writing or being overtaken by the data writing when reading the data from the memory.

The maximum value control signal S112 is set so that an integer multiple of the maximum memory address value becomes close to the predetermined number of horizontal sampling points in the standard signal state, that is, the write address maximum values are set at approximately equal values like “227” and “225” as shown in FIG. 5, while in FIG. 4 the write address maximum values are set so that the maximum value “141” is considerably different from the other maximum values “255”. Thereby, the range where the data reading does not overtake the data writing or is not overtaken by the data writing even when a non-standard signal is input and thereby the horizontal sync pulse is disordered, can be significantly increased as compared with the case of FIG. 4.

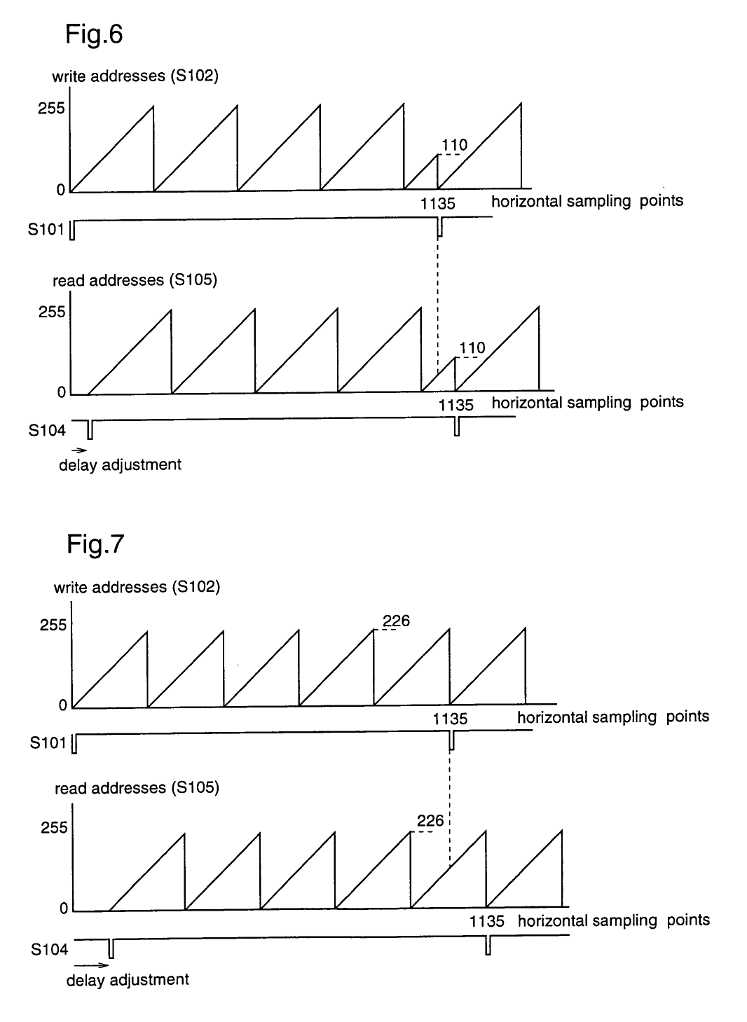

FIG. 6 shows the relationship between the horizontal sampling points and the write addresses (read addresses) of the memory in the case where a standard signal is input in the PAL system, a sampling frequency four times as high as a chrominance subcarrier frequency (4.43 MHz) is used for both the first clock S109 and the second clock S110, and there is no thinning-out in the horizontal direction. In this case, a memory having no thinning-out in the horizontal direction and being constituted by 256 addresses is employed. In FIG. 6, the abscissa shows the horizontal sampling points, and the address value increments by “1” every time the number of horizontal sampling points increments by 1, and the address value returns to the initial address value “0” when it exceeds the maximum value.

FIG. 7 shows the relationship between the horizontal sampling points and the write addresses (read addresses) of the memory in the case where a standard signal is input in the PAL system, a sampling frequency four times as high as a chrominance subcarrier frequency (4.43 MHz) is used for both the first clock S109 and the second clock S110, and there is no thinning-out in the horizontal direction. To be specific, FIG. 7 shows the relationship between the horizontal sampling points and the write addresses (read addresses) of the memory in the case where limiter processing is added in controlling writing and reading of data into/from the memory, and the memory is constituted by 256 addresses. In FIG. 7, the abscissa shows the horizontal sampling points, and the address value increments by “1” every time the number of horizontal sampling points increments by 1, and the address value returns to the initial address value “0” when it exceeds the maximum value.

In FIG. 6, when the horizontal sync pulse S101 is input, the write address S102 is reset to the initial address value “0”, and thereafter, the write address S102 is up-counted at every first clock. Since the memory size for one line period is 1135 addresses in the PAL broadcasting, when the maximum value of the maximum value control signal S112 is set at “255”, the address value returns to “0” when it exceeds the maximum value “255”. This up-counting is repeated four times until the next horizontal sync pulse S101 is input, and the line final value of the write address S112 from when the next horizontal sync pulse S101 is input to when the write address counter 102 is reset becomes “110” (1135=256×4+111). As for the start position of the read address S105, for example, “55” that is half the line final value of the write address is set as a delay difference according to the delay control signal S113. Therefore, even when the horizontal sync pulse is disordered and thereby a deviation of 55 clocks occurs in the horizontal direction when a video tape on which a non-standard signal in the PAL system is recorded is played back with a video tape recorder, it is possible to constitute a circuit in which the data to be read does not overtake the data to be written or is not overtaken by the data to be written, when reading the data from the memory.

In FIG. 7, when the horizontal sync pulse S101 is input, the write address S102 is reset to the initial address value “0”, and thereafter, the write address S102 is up-counted at every first clock. Since the maximum value of the write address S112 is set at “226”, the address value returns to “0” when it exceeds the maximum value “226”. This up-counting is repeated four times until the next horizontal sync pulse S101 is input, and the line final value of the write address S112 from when the next horizontal sync pulse S101 is input to when the write address counter 102 is reset becomes “226” (1135=227×5). As for the start position of the read address S105, for example, “113” that is half the line final value of the write address is set as a delay difference according to the delay control signal S113. Therefore, even when the horizontal sync pulse is disordered and thereby a deviation of 113 clocks occurs in the horizontal direction when a video tape on which a non-standard signal of the PAL system is recorded is played back with a video tape recorder, it is possible to constitute a circuit in which, when reading the data written in the memory, the data to be read does not overtake the data to be written or is not overtaken by the data to be written. The maximum value control signal S112 is set so that an integer multiple of the maximum memory address value is close to the predetermined number of horizontal sampling points in the standard signal state, whereby the range where the data reading does not overtake the data writing or is not overtaken by the data writing even when a non-standard signal is input and thereby the horizontal sync pulse is disordered, can be significantly increased.

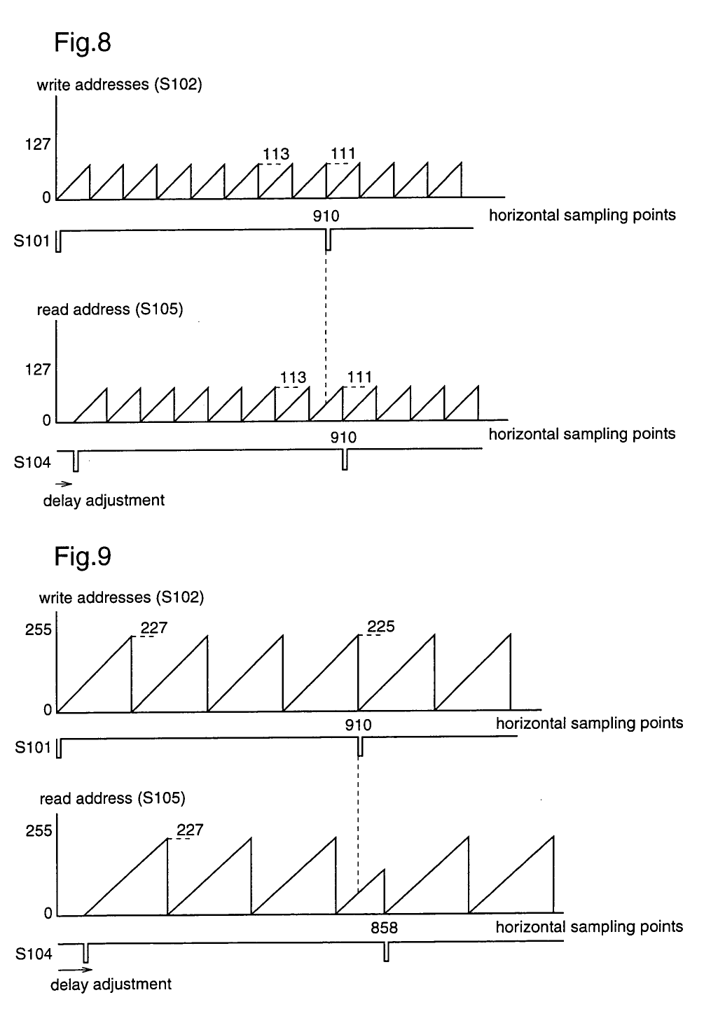

FIG. 8 shows the relationship between the horizontal sampling points and the write addresses (read addresses) of the memory in the case where a standard signal is input in the NTSC system, a sampling frequency four times as high as a chrominance subcarrier frequency (3.58 MHz) is used for both the first clock S109 and the second clock S110, and there is no thinning-out in the horizontal direction. More specifically, FIG. 8 shows the relationship between the horizontal sampling points and the write addresses (read addresses) of the memory in the case where limiter processing is added in controlling writing and reading of data into/from the memory. In this case, the maximum number of memory addresses is set at “128”, and the maximum value of the write address S112 is set at “113”. In FIG. 8, the abscissa shows the horizontal sampling points, and the address value increments by “1” every time the number of horizontal sampling points increments by 1, and the address value returns to the initial address value “0” when it exceeds the maximum value.

In FIG. 8, when the horizontal sync pulse S101 is input, the write address S102 is reset to the initial address value “0”, and thereafter, the write address S102 is up-counted at every first clock. Since the maximum value of the write address S112 is set at “113”, the address value returns to “0” when it exceeds the maximum value “113”. This up-counting is repeated seven times until the next horizontal sync pulse S101 is input, and the line final value of the write address S112 from when the next horizontal sync pulse S101 is input to when the write address counter 102 is reset becomes “111” (910=114×7+112). As for the start position of the read address S105, for example, “56” that is half the line final value of the write address is set as a delay difference according to the delay control signal S113. Therefore, even when the horizontal sync pulse is disordered and thereby a deviation of 56 clocks at maximum occurs in the horizontal direction when a video tape on which a non-standard signal of the NTSC system is recorded is played back, it is possible to constitute a standard signal without the data reading overtaking the data writing or being overtaken by the data writing when reading the data from the memory. The maximum value control signal S112 is set so that an integer multiple of the maximum memory address value becomes close to the prescribed number of horizontal sampling points in the standard signal state, whereby the range where the data to be read does not overtake the data to be written or is not overtaken by the data to be written even when the non-standard signal is input and thereby the horizontal sync pulse is disordered, can be significantly increased.

As described above, in the clock conversion apparatus according to the first embodiment, when a signal processed by a first clock is converted into a signal synchronized with a second clock, the number of addresses of a memory for holding a video signal corresponding to one horizontal line period is significantly reduced, and the video signal corresponding to one horizontal line period is written in and read from the memory over plural times, whereby the capacity of the memory can be reduced, and the circuit scale can be reduced not only when the apparatus deals with a single broadcasting system but also when it deals with plural broadcasting systems. Further, since an integer multiple of the maximum value of the memory address is set so as to be close to the number of sampling points in the horizontal period, even when a non-standard signal is input and thereby the horizontal sync pulse is disordered as in the case where a video tape recorder is played back, the written data can be read from the memory without the data reading overtaking the data writing or being overtaken by the data writing.

While in this first embodiment the first clock and the second clock have the same frequency, these clocks may be different types of clocks having different frequencies.

FIG. 9 shows, in the case where different types of clocks are used and the maximum number of memory addresses is set at “227”, the relationship between the horizontal sampling points and the write addresses (read addresses) of the memory when a standard signal is input in the NTSC system, a sampling frequency (=14.3 MHz) four times as high as a chrominance subcarrier frequency (3.58 MHz) is used for the first clock S109 and a sampling frequency (=13.5 MHz) four times as high as a chrominance subcarrier frequency (3.38 MHz) is used for the second clock S110, and there is no thinning-out in the horizontal direction. In this case, since 107 horizontal sampling points (=114×858/910) are set for delay adjustment, when the data written in the memory are read until the horizontal sync pulse is disordered and a deviation of maximum 107 clocks occurs in the horizontal direction in the case where a video page in which a non-standard signal of the NTSC system is recorded is played back with a video tape recorder, it is possible to constitute a standard signal without the data reading overtaking the data writing or being overtaken by the data writing. In FIG. 9, “910” and “858” are the numbers of horizontal sampling points which are defined in IEEE ITU656 in the case where the sampling frequencies are 14.3 MHz and 13.5 MHz, respectively, and “114” is half the maximum number of memory addresses “227”. The first clock and the second clock are not restricted to those mentioned above, and the second clock may have a frequency higher than that of the first clock. Further, the maximum number of memory addresses is not restricted to “227”.

Furthermore, the clock conversion apparatus may be implemented by any hardware construction so long as it can execute a method in which, using a memory that can perform writing and reading independently on the basis of different clocks, an amount of data larger than the capacity of the memory are written into the memory over plural times, and the written data are read from the memory over plural times.

Moreover, while in this first embodiment the maximum write address and the maximum read address of the memory are the same values, these addresses may be different values, and the same effects as described for the first embodiment can be obtained except that resolution changes.

[Embodiment 2]

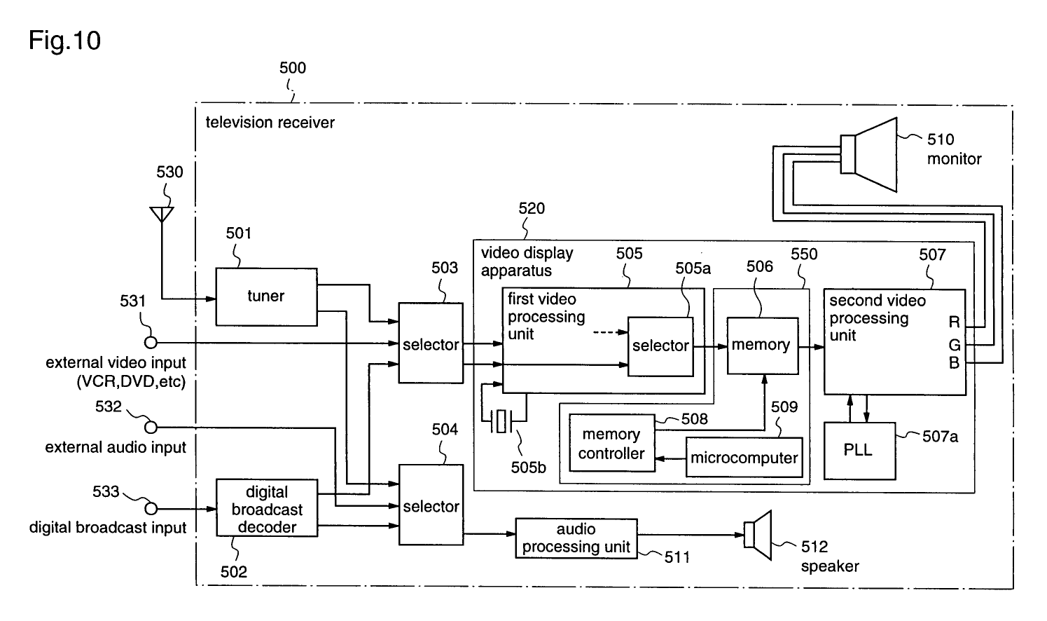

FIG. 10 is a block diagram illustrating the construction of a television receiver in which a video display having a clock conversion apparatus according to the first embodiment is incorporated. In FIG. 10, reference numeral 501 denotes a tuner connected to an antenna 530 for terrestrial analog broadcasting; numeral 502 denotes a digital broadcast decoder for decoding a digital broadcast signal such as an RF signal inputted to a digital broadcast input 533; numeral 503 denotes a selector for selecting one from among a demodulated video signal from the tuner 501, a playback video signal from such as a VCR or a DVD player, which is supplied from an external video input 531, and a digital video signal decoded by the digital broadcast decoder 502; numeral 504 denotes a selector for selecting one from among a demodulated audio signal from the tuner 501, a playback audio signal from such as a VDR or a DVD player, that is supplied from an external audio input 532, and a digital audio signal decoded by the digital broadcast decoder 502; numeral 520 denotes a video display unit for processing the video signal selected by the selector 503 and displaying it on a monitor (display device) 510; and numeral 511 denotes an audio processing unit for processing the audio signal selected by the selector 504 and outputting it to a speaker 512.

Further, in the video display unit 520, reference numeral 505 denotes a first video processing unit which performs first video processing for processing a digital video signal obtained by inputting the output of the selector 503 into an A/D converter (not shown), in synchronization with a first clock; numeral 505a denotes an internal selector of the first video processing unit 505; numeral 505b denotes a quartz oscillator for supplying a clock to the first video processing unit 505; numeral 506 denotes a memory for holding the output of the first video processing unit 505; numeral 508 denotes a memory controller for controlling the memory 506 under a setting by a microcomputer 509; numeral 507 denotes a second video processing unit which performs second video processing for processing the output of the first video processing unit 505 that is obtained through the memory 506, in synchronization with a second clock; and numeral 507a denotes a PLL for generating the second clock. Further, numeral 550 denotes a clock conversion unit comprising the memory 506, the memory controller 508, and the microcomputer 509. The clock conversion unit 550 corresponds to the clock conversion apparatus according to the first embodiment. The memory controller 508 comprises the first counter circuit 10, the second counter circuit 11, and the delay adjustment circuit 103 which are shown in FIG. 1. The microcomputer 509 sets an upper limit value of count on the limit value generation circuit (register) 1026 (1056) shown in FIG. 2 according to the maximum value control signal S112 shown in FIG. 1. Further, the microcomputer 509 sets an amount of delay on the delay adjustment circuit 103 shown in FIG. 1 according to a delay difference signal S113. The tuner 501 outputs a horizontal sync pulse S101 to the first counter circuit 10 and the second counter circuit 11 shown in FIG. 1 directly or through the delay adjustment circuit 103, respectively.

The video display unit 520 may be constituted by a single semiconductor integrated circuit, and the microcomputer 509 and the memory 506 may be incorporated in or externally connected to the video display unit 520. Further, the microcomputer 509 may be a station-selection microcomputer.

Next, the operation will be described.

First of all, the selectors 503 and 504 select one from among reception of terrestrial analog broadcasting, playback of a package media such as VCR (Video Casette Recorder) or DVD (Digital Versatile Disk), and reception of digital broadcasting. It is assumed that reception of terrestrial analog broadcasting is selected. The terrestrial analog broadcasting received by the antenna 530 is input to the tuner 501 wherein a desired channel is selected, and an analog composite video signal and a demodulated audio signal as demodulated outputs are input to the video display unit 520 and the audio processing unit 511 through the selectors 503 and 504, respectively.

The analog composite video signal inputted to the video display unit 520 is converted into a digital signal by an A/D converter (not shown), and output to the first video processing unit 505. The first video processing unit 505 performs video signal processing such as Y/C separation and color demodulation on the basis of the first clock having a frequency according to the broadcasting system such as NTSC or PAL. A Y signal and color-difference signals after the video signal processing are output through the selector 505a in the first video processing unit 505, and the outputted video signal is input to the memory 506 so as to be synchronized with the second clock. The video signal synchronized with the second clock in the memory 506 is input to the second video processing unit 507, wherein display processing (i.e., improvement of image quality such as changing the gain of contrast or brightness, synchronization with the clock of the video signal, and conversion into RGB signals) is carried out in synchronization with the second clock. For example, the first clock obtained from the quartz oscillator 505b is a clock synchronized with a burst signal, which is called a burst lock clock, and the frequency thereof depends on the broadcasting system. On the other hand, the second clock obtained from the PLL circuit 507a is a clock synchronized with the horizontal frequency, which is called a horizontal line lock clock or the like, and the frequency thereof depends on the screen size of the monitor 510. The RGB signals outputted from the second video processing unit 507 are input to the motor 510 to display a picture.

On the other hand, the demodulated audio signal from the tuner 501, which is selected by the selector 504, is subjected to audio signal processing by the audio signal processing unit 511, and a sound is output from the speaker 512.

Further, when the external video input 531 and the external audio input 532 are selected by the selectors 503 and 504, respectively, a playback analog signal from a VCR or a DVD connected to these input terminals can be selected. The operation in this case is identical to that in the case where the tuner 501 is selected.

On the other hand, when the output of the digital broadcasting decoder 502 is selected, since the digital video signal has already been separated into a Y signal and color-difference signals when it is outputted from the digital broadcasting decoder 502, the video signal passes through the first video processing unit 505 without being processed, and is output to the memory 506 through the selector 505a in the first video processing unit 505.

By the way, the memory 506 corresponds to the memory 107 shown in FIG. 1, and the capacity of the memory 506 can be made smaller than one horizontal period by writing and reading a video signal corresponding to one horizontal period over plural times under control of the memory controller 508.

The memory controller 508 is constituted by the first counter circuit 10, the second counter circuit 11, and the delay adjustment circuit 103 which are shown in FIG. 1, and the limit values of the write maximum value limiter 102 and the read maximum value limiter 105 are set by the microcomputer 509 such as a station-selection microcomputer, according to the broadcasting system. The interpolation circuit 106 shown in FIG. 1 is included in the first video processing unit 505.

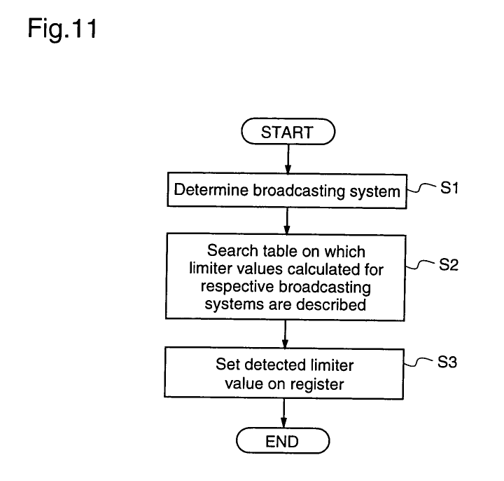

FIG. 11 shows a process flow of the microcomputer 509. In step S1 (determination step), the broadcasting system of the received TV signal is determined to determine the broadcasting system of the digital video signal inputted to the first video processing unit 505. This determination is carried out by plural processings as follows: discriminating the broadcasting system between the PAL system and the NTSC system according to whether the frequency of the vertical sync signal is 50 Hz or 60 Hz, and detecting the frequency of the horizontal sync signal to minutely classify the PAL system or the NTSC system. Further, the discrimination of the frequency is carried out by inputting the sync signal (not shown) outputted from the tuner 501, to the microcomputer 509. Next, a table showing the limiter values (upper limits of count values) which have previously been calculated for the respective broadcasting systems is searched in step S2 (search step), and the detected limiter value is set on the registers of the first and second counter circuit 10 and 11, i.e., the limit value generation circuits 1026 and 1056 of the decoders 102a and 105a.

The limiter value is set only once as long as the broadcasting system is not changed, whereby the memory controller 508 successively generates the addresses as shown in FIG. 9, writes one horizontal line of data into a memory having a capacity less than one horizontal line, over plural times. At the point in time when the n-th writing (n: an integer not less than 1) has been carried out by half, the n-th reading is started. When overwriting of the (n+1)th data in the same memory has been carried out by half, the n-th reading is completed. Therefore, transition of data from on the first clock to on the second clock can be carried out utilizing the small memory capacity, without the data reading overtaking the data writing or being overtaken by the data writing.

Thereby, even in the case where TV broadcasts of various broadcasting systems are received, when a video signal transits from on the first clock to on the second clock, the capacity of a memory to be used for this transition can be made smaller than one horizontal period.

As described above, in the video display apparatus such as the television receiver according to the second embodiment, when the video signal transits from on the first clock to on the second clock, the capacity of the memory to be used for this transition can be made smaller than the capacity corresponding to one horizontal period, thereby achieving a reduction in circuit scale or circuit area as well as a reduction in power consumption. Further, since the limiter value to be written in the register is changed by the microcomputer, the above-described merits can be obtained without changing the circuit construction even when receiving TV broadcasts of different broadcasting systems.

While in this second embodiment the limiter value to be written in the register is changed by the microcomputer, the limiter value may be set by manual operation.

While in this second embodiment a television receiver for terrestrial analog broadcasting which is adaptable to digital broadcasting is described as an example, a television receiver for only terrestrial analog broadcasting or a television receiver for only digital broadcasting may be used. Further, it may be a video display apparatus for displaying various video sources which are externally inputted.

Further, transition of a video signal from on the first clock to on the second clock may be carried out for realizing so-called picture-in-picture.

Furthermore, while in the first and second embodiments the first and second counter circuits perform up-counting, these counter circuits may perform down-counting.

What is claimed is:

1. A clock conversion apparatus for converting data synchronized with a first clock into data synchronized with a second clock, said apparatus comprising:
a memory having addresses less than addresses required for storage of data corresponding to a predetermined period, and being able to execute a writing operation and a reading operation independently from each other using a clock for writing and a clock for reading, respectively;
a first counter circuit for counting the first clock, and generating write addresses of the memory so that the data corresponding to the predetermined period can be written into the memory over plural times; and
a second counter circuit for counting the second clock, and generating read addresses of the memory so that the data corresponding to the predetermined period, which have been written in the memory, can be read from the memory over plural times.

2. A clock conversion apparatus for converting data synchronized with a first clock into data synchronized with a second clock, said apparatus comprising:
a memory having addresses less than addresses required for storage of data corresponding to a predetermined period, and being able to execute a writing operation and a reading operation independently from each other using a clock for writing and a clock for reading, respectively;
a first counter circuit for starting count of the first clock on receipt of a writing start reference signal indicating a reference timing of starting data writing into the memory, and generating write addresses of the memory so that the data corresponding to the predetermined period can be written in the memory over plural times; and
a second counter circuit for starting count of the second clock from a reading start reference signal indicating a reference timing of starting data reading from the memory, and generating read addresses of the memory so that the data corresponding to the predetermined period, which have been written in the memory, can be read over plural times.

3. A clock conversion apparatus for converting data synchronized with a first clock into data synchronized with a second clock, said apparatus comprising:
a memory having addresses less than addresses required for storage of data corresponding to a predetermined period, and being able to execute a writing operation and a reading operation independently from each other using a clock for writing and a clock for reading, respectively;
a first counter circuit for starting count of the first clock on receipt of a writing start reference signal indicating a reference timing of starting data writing into the memory, and generating write addresses of the memory so that the data corresponding to the predetermined period can be written into the memory over plural times;
a second counter circuit for starting count of the second clock from a reading start reference signal indicating a reference timing of starting data reading from the memory, and generating read addresses of the memory so that the data corresponding to the predetermined period, which have written in the memory, can be read over plural times; and
a delay adjustment circuit capable of adjusting a delay time, which delays the writing start reference signal to generate the reading start reference signal.

4. A clock conversion apparatus for converting data synchronized with a first clock into data synchronized with a second clock, said apparatus comprising:
a memory having addresses less than addresses required for storage of data corresponding to a predetermined period, and being able to execute a writing operation and a reading operation independently from each other using a clock for writing and a clock for reading, respectively;
a first counter circuit for starting count of the first clock on receipt of a writing start reference signal indicating a reference timing of starting data writing into the memory, and generating write addresses of the memory, which repeat increase or decrease within a predetermined range of addresses of the memory, so that the data corresponding to the predetermined period can be written in the memory over plural times;
a second counter circuit for starting count of the second clock from a reading start reference signal indicating a reference timing of starting data reading from the memory, and generating read addresses of the memory, which repeat increase or decrease within a predetermined range of addresses of the memory, so that the data corresponding to the predetermined period which are written in the memory can be read over plural times; and
a delay adjustment circuit capable of adjusting a delay time, which delays the writing start reference signal to generate the reading start reference signal.

5. A clock conversion apparatus for converting data synchronized with a first clock into data synchronized with a second clock, said apparatus comprising:
a memory having addresses less than addresses required for storage of data corresponding to a predetermined period, and being able to execute a writing operation and a reading operation independently from each other using a clock for writing and a clock for reading, respectively;
a first counter circuit for starting count of the first clock on receipt of a writing start reference signal indicating a reference timing of starting data writing into the memory, and generating write addresses of the memory so that the write addresses repeat increase or decrease within a predetermined range of addresses of the memory, and the last increase or decrease for every predetermined period is carried out within a range of addresses narrower than the predetermined range of addresses, thereby enabling writing of the data corresponding to the predetermined period into the memory over plural times;
a second counter circuit for starting count of the second clock from a reading start reference signal indicating a reference timing of starting data reading from the memory, and generating read addresses of the memory so that the read addresses repeat increase or decrease within a predetermined range of addresses of the memory, and the last increase or decrease for every predetermined period is carried out within a range of addresses narrower than the predetermined range of addresses, thereby enabling reading of the data corresponding to the predetermined period, which have been written in the memory, over plural times; and
a delay adjustment circuit capable of adjusting a delay time, which delays the writing start reference signal to generate the reading start reference signal.

6. A clock conversion apparatus as defined in any of claims 1 to 5 wherein
the data corresponding to the predetermined period are written in the memory using such write addresses that a multiple of a maximum write address value becomes close to the number of samples of data that are sampled at the first clock within the predetermined period; and
the data are read from the memory using such read addresses that a multiple of a maximum read address value becomes close to the number of samples of data that are sampled at the second clock.

7. A clock conversion apparatus as defined in any of claims 1 to 5 wherein
the data corresponding to the predetermined period are written in the memory using such write addresses that a multiple of a maximum write address value becomes close to the number of samples of data that are sampled at the first clock within the predetermined period; and
the data are read from the memory using read addresses having a maximum value equal to the maximum value of the write addresses.

8. A clock conversion apparatus as defined in any of claims 1 to 5 wherein
the predetermined period is one horizontal sync period.

9. A clock conversion apparatus as defined in any of claims 1 to 5 wherein
the first counter circuit comprises:
a write address counter for counting the first clock to create the write addresses; and
a write maximum value limiter for comparing the write address outputted from the write address counter with a settable write maximum value, and resetting the write address counter when the write address becomes equal to the write maximum value.

10. A clock conversion apparatus as defined in any of claims 1 to 5 wherein
the second counter circuit comprises:
a read address counter for counting the second clock to create the read addresses; and
a read maximum value limiter for comparing the read address outputted from the read address counter with a settable read maximum value, and resetting the read address counter when the read address becomes equal to the read maximum value.

11. A clock conversion method for converting data synchronized with a first clock into data synchronized with a second clock, said method comprising:
generating write addresses on the basis of the first clock so that data corresponding to a predetermined period are written over plural times into a memory which has addresses less than addresses required for storage of the data corresponding to the predetermined period, and is able to execute a writing operation and a reading operation independently from each other using a clock for writing and a clock for reading, respectively; and
generating read addresses on the basis of the second clock so that the data corresponding to the predetermined period are read from the memory over plural times.

12. A video display apparatus comprising:
a first video processing unit for subjecting a digital video signal to first video processing on the basis of a first clock;
a clock conversion unit for converting the digital video signal which is outputted from the first video processing unit and synchronized with the first clock into a digital video signal synchronized with a second clock;
a second video processing unit for subjecting the digital video signal outputted from the clock conversion unit to second video processing on the basis of the second clock;
a display device for displaying the digital video signal outputted from the second video processing unit; and
said clock conversion unit comprising:
a memory having a capacity less than one horizontal line of the digital video signal outputted from the first video processing unit, and being able to execute a writing operation and a reading operation independently from each other using a clock for writing and a clock for reading, respectively; and
a memory controller for controlling the memory so that the digital video signal outputted from the first video processing unit are written into the memory over plural times for every horizontal line, and the data corresponding to each horizontal line, which are written in the memory, can be read over plural times.

13. A video display apparatus as defined in claim 12, wherein said memory controller comprises:
a first counter circuit for starting count of the first clock on receipt of a writing start reference signal indicating a reference timing of starting data writing into the memory, and generating write addresses of the memory so that the one horizontal line of data can be written into the memory over plural times; and
a second counter circuit for starting count of the second clock from a reading start reference signal indicating a reference timing of starting data reading from the memory, and generating read addresses of the memory so that the one horizontal line of data which are written in the memory can be read over plural times.

14. A memory address setting method for a video display apparatus comprising:
a first video processing unit for subjecting a digital video signal to first video processing on the basis of a first clock;
a clock conversion unit for converting the digital video signal which is outputted from the first video processing unit and synchronized with the first clock into a digital video signal synchronized with a second clock;
a second video processing unit for subjecting the digital video signal outputted from the clock conversion unit to second video processing on the basis of the second clock;
a display device for displaying the digital video signal outputted from the second video processing unit; and
said clock conversion unit comprising:
a memory having addresses less than addresses required for storage of data corresponding to a predetermined period, and being able to execute a writing operation and a reading operation independently from each other using a clock for writing and a clock for reading, respectively;
a first counter circuit for generating write addresses of the memory on the basis of the first clock so that the data corresponding to the predetermined period are written over plural times; and
a second counter circuit for generating read addresses of the memory on the basis of the second clock so that the data corresponding to the predetermined period are from the memory over plural times; and
said memory address setting method comprising:
a step of determining a broadcasting system of the digital video signal inputted to the first video processing unit;
a step of detecting upper limits or lower limits of count values of the first and second counter circuits corresponding to the determined broadcasting system, according to the broadcasting system; and
a step of setting the detected upper limits or lower limits of the count values on the first and second counter circuits.
